(19) United States
(12) Patent Application Publication
(10) Pub. No.: US 2004/0129212 A1
(43) Pub. Date: Jul. 8, 2004

(54) Apparatus and method for delivery of reactive chemical precursors to the surface to be treated

(76) Inventors: Pradad N. Gadgil, Santa Clara, CA (US); Shmuel Erez, San Jose, CA (US)

Correspondence Address: SAWYER LAW GROUP LLP, P O BOX 51418, PALO ALTO, CA, 94303, US

(21) Appl. No.: 10/370,883

(22) Filed: Feb. 21, 2003

Related U.S. Application Data
(63) Continuation-in-part of application No. 10/019,244, filed on May 20, 2002.
Application No. 10/019,244 is a 371 of international application No. PCT/US00/17202, filed on Jun. 23, 2000.
(63) Continuation-in-part of application No. 10/288,345, filed on Nov. 4, 2002.

(51) Int. Cl. C23C 16/00

(52) U.S. Cl. 118/715; 118/728

(57) ABSTRACT

The present invention provides an apparatus and method for radical-assisted monolayer processing in a reactor with linear injectors arranged in diametrical direction of the substrate and injecting reactive gases or radicals sequentially onto the treated substrate surface with a relative motion between the injectors and the substrate. In the first step, a first chemical precursor is injected from the first injector; in the second step carrier gas is pulsed to sweep the surface. In the third step, second precursor, preferably a radical is injected on the substrate to affect rapid chemical reaction with the chemisorbed monolayer of the first chemical precursor. Finally in the fourth step, only radicals are injected on the surface to complete the reaction cycle and to sweep the reaction by-products and to prepare the surface. During each gas injection step the substrate rotates at least half the rotation. The reactor can be operated in a pulse precursor and continuous radical flow or constant precursor and constant radical flow modes to modulate processing rate. Operational advantages of such an apparatus and process are lower process temperature, reduction in ion damage and rapid and precision monolayer processing with highly conformal surface coverage over the entire substrate surface.

### CROSS-REFERENCE TO RELATED APPLICATIONS

This application is a Continuation-In-Part of co-pending U.S. patent application entitled “Apparatus for Atomic Layer Chemical Vapor Deposition”, Ser. No. 10/019,244, filed on May 20, 2002, and co-pending U.S. patent application entitled “Apparatus and Method for Treating Objects with Radicals Generated from Plasma”, Ser. No. 10/288,345, filed on Nov. 4, 2002, both incorporated herein by reference.

### FIELD OF THE INVENTION

The present invention relates to manufacturing of semiconductor devices, and more particularly, to an apparatus and method for delivery of reactive chemical precursors to the surface of a substrate which have to be treated or coated, e.g., with a synchronized pulse downstream plasma processing apparatus for processing of thin films on substrates, e.g., in semiconductor device fabrication or in a similar field.

### BACKGROUND OF THE INVENTION

Manufacturing of advanced integrated circuits (ICs) in the microelectronic industry is accomplished through numerous and repetitive steps of deposition, patterning, and etching of thin films on the surface of silicon wafers. An extremely complex, monolithic and three-dimensional structure with complex topography of variety of thin film materials such as semiconductors, insulators and metals is generated on the surface of a silicon wafer in a precisely controlled manner.

Processes of deposition and etching involve chemical reactions in which solid material is either added or removed from the substrate, and the activation energy required to affect the desired chemical reactions in a controlled fashion, is supplied by various means such as heat, light or electromagnetic excitation as applied to the gas phase or to the substrate or both, and the processes are commonly known as thermal, optical or plasma processes, respectively.

Plasma is conveniently generated by applying a time varying electromagnetic field to the gaseous medium, which generates high-energy electrons that collide inelastically with gas molecules and lead to their ionization and fragmentation in multiple ways. Plasma generates variety of species among others such as ions, neutral but reactive radicals with an unpaired electron, electronically activated neutrals e.g. metastables with long life times. However, in plasma a polyatomic molecule dissociates in multiple ways and forms numerous species through an extremely complex phenomenon, which is rather poorly understood. Also, chemical reactions of such fragmented species among themselves in the gas phase and with the substrate are rather poorly defined. More importantly, impact of high-energy ions with a substrate, on which a large number of electronic devices are being fabricated, can cause severe electrical damage and contribute to their failure. Hence, it is highly desirable to eliminate electrically charged energetic entities from plasma and use the remnant energetic species with definite energy quanta to affect desired chemical reactions in a controlled manner. Chemically the most reactive species with a well defined quanta of energy and hence the most desirable ones that can be extracted and used from plasma are radicals that participate in the chemical processes in predictable ways. Thus, interaction of radicals with chemical precursors offers tremendous benefits to vapor phase processing in improved control, reduced electrical damage and superior quality product. Moreover, chemical reactions comprising radicals lead to significant lowering reaction temperature due to their high reactivity, and electrical neutrality of the radicals results in to non-directional (isotropic) chemical processing of the substrate.

A radical is formed by “homolytic” fission of a chemical bond between two atoms or two species (A..B) in which an electron pair that forms a chemical bond is equally split. A radical thus carries an unpaired electron (a dangling bond) and is an extremely reactive and electrically neutral entity. In case of diatomic gases such as H₂, direct electron impact dissociation of hydrogen in the plasma leads to a variety of species such as hydrogen ion H⁺, excited atomic hydrogen H*, excited molecular hydrogen H₂*, atomic H, and secondary electrons e⁻. For a diatomic molecule such as H₂ that dissociates in to two equal fragments, a radical and an atom have exactly same electronic configuration and a radical of hydrogen is denoted hereafter as .H. In case of a polyatomic molecule such as CH₄, dissociation of H—CH₃ bond forms a methyl radical, which is denoted by the symbol .CH₃. In general a radical of a chemical species A, is hereafter denoted as .H

M. J. Kushner in Journal of Applied Physics, vol. 63, p.2532 (1988) studied interactions of silane (SiH₄) with a variety of species in H₂ plasma in terms of reaction probabilities in which it was found that atomic hydrogen with well-defined energy quanta could generate .SiH₃ radicals. At the basis of radical generation process is relative bond strength or energy (expressed in kJ/mole) between the bonds within a stable molecule and the product that is formed by a reaction between a radical and such a molecule. If the latter is higher, then a radical of a non-condensable gas will react with a stable molecule. It can be summarized as a reaction between an atom of a non-condensable gas .A and a stable molecule B-X (condensable or non-condensable) by the equation:

.A+B-X→A-X+.B

This reaction is feasible if the bond energies are A-X>B-X. It generates a single new product radical .B that is chemically well defined with predictable chemical behavior.

Furthermore, metastable species of inert gases such as helium, argon, xenon, etc. that are excited to the higher energy level have a finite-quanta of energy that can be suitably employed to activate stable chemical molecules of other species and desired radicals may be obtained as well.

Related to our invention, herein, gases or vapors are defined according to their mode of interaction with plasma or a high-energy electromagnetic excitation. A non-condensable gas or a vapor is defined as a gas or a vapor that does not decompose in to one or more gaseous components and a solid residue and/or it is a gas or vapor that does not react vigorously and destructively with the material of construction of the plasma cavity or enclosure when exposed to an external excitation such as plasma or high-energy electromagnetic radiation. Examples of non-condensable gases are, but not limited to: hydrogen, helium, argon, xenon, oxygen, nitrogen, etc. Condensable gases or vapors are the ones that obviously do not satisfy the criteria described above. Examples of condensable gases are, but not limited to: hydrogen sulfide, hydrogen selenide, arsine, phosphine, silane, diborane, tungsten hexafluoride, hydrogen chloride, carbon tetra-fluoride, nitrogen tri-fluoride, CFCs, and chlorine etc.

Thus in summary, metastables of inert gases and atomic species or radicals of non-condensable gases can be suitably employed to generate reactive radicals of the desired species downstream. However, due to their high reactivity, radical yield from plasma is strongly dependent on the surface recombination and a strong surface catalytic effect is frequently observed. Moreover, lifetime of radicals and also metastables is also another crucial factor that must be carefully weighed in while considering their use to carry out desired reactions. Strong surface recombination and/or longer path lengths are detrimental to the viability of a radical to traverse to the substrate surface through the gas phase from the point of origin. Such factors are crucially important in order to effectively employ energetic species from the plasma to the advantage and special care is required to realize practical benefits of their reactivity.

As described in U.S. Pat. No. 6,083,363 issued in 2000 to K. Ashtiani, et al, a grounded grid is used to filter ions and electrons, so as to let radicals flow downstream and away from the plasma. A chemical precursor is mixed with the radicals, and a thin film is deposited on a stationary substrate underneath. In yet another mode, radicals are employed to activate a reactant in a well-known technique of Remote Plasma Enhanced Chemical Vapor Deposition (RPE-CVD) process. In such a configuration, plasma is generated far away from the chemical precursor injection ports, where the ion and electron concentration drops significantly by gas phase recombination. For details, please refer to G. Lukovsky, D. V. Tsu and R. J. Markunas, chapter 16, of the Handbook of Plasma Processing Technology referred above. Both these approaches involve longer path lengths or larger operational volumes.

T. L. Hukka et al., in Materials Research Society Symposium Proceedings, vol. 282, p. 671 (1993), no month, published their paper describing low-pressure diamond growth using a secondary radical source. Pulsing flows of CHCl₃/CH₄ and H₂ were mixed with a constant flow of thermally generated fluorine atoms to obtain alternate pulses of .CCl₃/.CH₃ and [H] in a collision-free flow to the surface such that the surface terminated with hydrogen atoms at the end of each ALD cycle. However, this process requires high temperatures to generate fluorine atoms and flow in the apparatus is a free flow, which results in to low rate of deposition.

Fujiwara et al, published synthesis of ZnSₓSe₁₋ₓ in J. Appl. Phys., vol. 74, p. 5510, November 1993, by employing atomic hydrogen generated through RF plasma and a metallic mesh ion filter. Also, S. M. Bedair published Atomic Layer Deposition (hereinafter referred to as ALD) process of silicon using dichlorosilane (SiH₂Cl₂) with atomic hydrogen [H] generated by hot-filament method in J. Vac. Sci. Technol., B 12(1), p. 179 (1994) dropping the deposition temperature from 90°° C. to 650° C. in which the surface terminated with hydrogen at the end of pulse sequence. In these processes, a hot tungsten filament that is used to generate hydrogen radicals, and a metallic mesh to filter ions can lead to undesirable issues such as contamination and decrease in reliability of operation.

Markunas et al. in the U.S. Pat. No. 5,180,435 described an apparatus and method for remote plasma enhanced chemical vapor deposition process to grow epitaxial films. In this apparatus, long path lengths required to achieve active ion filtering and reactive chemistry mixing prior to deposition on the substrate that is stationary. The active chemistry is injected through a ring injector within the chamber, which increases the chamber volume considerably.

Brors et al. in the U.S. Pat. No. 5,551,985 described an apparatus and method for chemical vapor deposition by laterally injecting process gases through multiple and individually adjustable side nozzles on a slowly rotating substrate. The entire substrate is covered simultaneously by flow through multiple adjustable nozzles, such that flow is substantially parallel to the deposition plane. Moreover, substrate rotation does not play active role in surface coverage but is employed to achieve temperature uniformity.

In the U.S. Pat. No. 5,637,146 granted to Chyi, a method and apparatus is described for the growth of nitride-based semiconductors. In this configuration, a large diameter atom source (an RF plasma) is placed within the chamber. Chemical precursors are injected through concentric or segmented rings placed around the atom source facing a rotating substrate. In this configuration, the entire substrate surface is exposed to the atom and ions flow, which at ultra-low pressure is substantially molecular in nature. The substrate rotation is employed to achieve temperature uniformity and not the surface coverage. Also chemical precursor is injected within the chamber volume.

Whereas, the U.S. Pat. No. 4,980,204 issued to Fujii in 1990 describes an apparatus and method to deposit thin films employing flow through plurality of vertical and long injector tubes set over the diameter of the substrate with individual fluid supply and control mechanisms that provide complete but uneven surface coverage of the substrate. In this configuration, substrate rotation is employed to improve the uniformity of deposition and not for surface coverage. The complexity in system configuration and operation for large diameter substrates can be significant and impractical. In addition, a provision of separate mass flow controllers for each tube makes the system highly complicated in design and extremely expensive to manufacture.

U.S. Pat. No. 4,105,810 issued in 1978 to Yamazaki et al. describes in one of the embodiments deposition of zinc borosilicate glass onto a rotating substrate by means of a linear injector in the form of a tube arranged above the substrate in a radial direction. As the tube has three sequential chemistry-release apertures, during the operation the flow depletes in the radial outward direction. This results in uneven deposition even with rotation in radial direction.

Aucoin et al in U.S. Pat. No. 5,443,647 described an apparatus and method for plasma chemical vapor deposition. In their apparatus, which has a pulsed plasma source, a liner injector in a large volume chamber pulses chemical precursors in active plasma. All the plasma-generated species diffuse towards the substrate placed downstream on a rotating pedestal. Almost all the ions are eliminated by gas phase recombination above the substrate surface and only radicals and activated species impinge the substrate thereby allowing atomic layer growth. However, in this invention, direct injection of chemical precursors in the active plasma dissociates or fragments the chemical precursor molecules in many ways than one. High-energy electrons in the plasma with varying kinetic energies lead to multiple pathways of dissociation of the reactive gas molecules. As a result, a clearly defined mode of reaction sequence by radicals alone is eliminated. Moreover, the large reactor volume results in to diffusive flow of the ions, radicals and excited species towards the substrate mounted downstream at a distance. All such factors slow the deposition process significantly.

Yet another invention by Sneh in U.S. Pat. No. 6,200,893 describes the apparatus and process sequence to achieve a variety of radical-assisted chemistries to deposit thin films of metals, oxides and nitrides thereof are described. In the invention, chemical precursors and radicals are sequentially injected from a common gas distributor such as a showerhead on a stationary substrate. In a showerhead, active chemical precursor and radicals share the same flow path and although time sequenced, involve both longer path length and significant radical-surface contact. Also, any adsorption of chemical precursor on the inner surfaces of the showerhead can be highly detrimental to survival of free radicals such as .H, .O and .NH etc. as described before. Moreover, in this invention the chemical processes employ radicals and chemical precursors sequentially but not together and are limited to reduction of a metal precursor to metal state and subsequent conversion to metal —OH or metal —NH group. Further, this particular invention places constraints on the gases that can be employed to generate radicals. For example, condensable gases that can decompose and lead to a solid residue such as silane (SiH₄), germane (GeH₄), methane (CH₄), diborane (B₂H₆), phosphine (PH₃), arsine (AsH₃), hydrogen sulfide (H₂S), hydrogen selenide (H₂Se) and many others cannot be practically introduced into the plasma cavity directly to obtain desired and reactive radical species.

Radicals generated by the interaction of .H and NF₃ can be effectively employed in downstream mode to etch silicon dioxide at or near room temperature as shown by Kikuchi—U.S. Pat. No. 5,620,559 and Fujimura et al., in the U.S. Pat. No. 6,107,215. Fluorine radicals generated in such an arrangement do not etch the surfaces of contact upstream, unless NF₃ is injected directly into the plasma cavity. However, this method uses long path length for ion-electron recombination ahead of the active plasma region and also long mixing length is interposed between the downstream chemical precursor injection port and the substrate. Both are detrimental to the net radical concentration downstream and the process as a whole. Moreover, this method of downstream reactive radical generation also does not offer independent pressure control of the downstream pressure and flow.

Recently, Sherman in U.S. Pat. No. 5,916,365 and U.S. Pat. No. 6,342,277 has described an apparatus and method for sequential chemical vapor deposition method employing radicals of gases such as hydrogen and oxygen over substrates in a longitudinal and free flow on a stationary substrate. The reactor configuration as described in these inventions involves closing the downstream throttle valve to backfill the chamber for surface saturation and opening it to purge. In the process cycle, chemical precursor and radicals are sequenced and chemical reactions are carried out without heating the substrate. In the apparatus and process described in this prior art, radicals and chemical precursors are not mixed in the gas phase prior to their impingement on to the substrate but are sequenced. The radical transport to the substrate surface by diffusion is slow and inefficient and can lead to significant recombinative losses.

ALD operates on the principle of a self-limiting mechanism of chemisorption and is thus rather frugal in the use of the quantity of the input chemicals since any excess chemical molecules than that needed to form a monolayer are redundant. Moreover, convective chemical transport to the surface coupled with an inert gas pulse to sweep excess reactive chemical can help in minimizing the chemical waste and may lead to substantial enhancement of the chemical utilization efficiency. Such factors are of significant value towards increased operating benefit and also to lower the downstream cleaning and abatement of the effluents.

U.S. Pat. No. 5,225,366 awarded to Yoder describes that a minimum exposure of 10¹⁵ molecules/cm² is needed to accomplish effective chemisorption to form a monolayer for an ALD process in a given pulse. This leads to 0.5 micro-moles/pulse of reactant for a 200 mm blanket silicon wafer, and for a patterned wafer with a surface area/blanket area ratio=100, it is as little as 50 micro-moles/pulse! The process of ALD is thus rather frugal in chemical consumption. This aspect has tremendous implications for large-scale environmentally benign manufacturing of electronic devices. Although in principle, the technique of ALD offers a variety of advantages over the industry prevalent techniques such as CVD and PVD, at present, it is being accepted in to the industry for a limited number of process applications. The reasons behind the limited applications of ALD are (a) sluggishness of a typical ALD process in the currently available apparatuses and (b) higher reaction temperatures for the chemical processes that can be detrimental to a variety of materials such as low-k dielectrics. A typical commercially available ALD apparatus completes one cycle in several seconds. This translates in to a deposition rate of few tens of Angstroms (a few nm) per minute. Moreover, a typical ALD apparatus cannot be used as a CVD apparatus and vice-a-versa holds true. This necessitates separate reactor systems for thick film applications.

What is clearly needed is an apparatus and method that could efficiently generate radicals from a variety of chemical species, condensable and non-condensable, and mixtures thereof that are well defined in chemical composition, in the gas phase at sufficiently high concentration to realize wide range of chemistries in the smallest volume and by employing shortest path length. Such an apparatus is described in detail in the U.S. patent application Ser. No. 10/288,345 filed by the same applicants on Nov. 4, 2002. Furthermore, such an apparatus, an efficient radical generator, must be combined with an efficient substrate processing apparatus in order to achieve the final goal of high-speed radical assisted monolayer processing with enhanced flexibility. However, following drawbacks need be eliminated from the existing ALD and CVD apparatus and technique:

Unstable fluid flow above the substrate and within the reactor;

(a) Depletion of reactive gas or vapor over the substrate surface which makes it impossible to achieve full surface coverage in shortest time frame;

(b) Improper materials of construction which do not allow minimization of radical recombination;

(c) Inadequate separation of highly reactive gases in operational space;

(d) Non-optimized path length of reactive gases within the apparatus;

(e) Non-optimized internal volume with inadequate pumping speed leading to longer residence time detrimental for rapid completion of an ALD cycle;

(f) Absence of reactors configured for maintenance and service in field;

(g) Insufficient reproducibility and repeatability of the processes.

An apparatus that satisfies these conditions, except appropriate materials and geometries for low radical-surface recombination is described in the U.S. patent application Ser. No. 10/019,244 filed May 20, 2002 by P. Gadgil.

### SUMMARY OF THE INVENTION

It is an object of the present invention to provide an apparatus and method for efficient delivery of process fluids, such as radical-containing gases and chemical precursors, to a surface to be processed. It is another object is to provide the aforementioned apparatus and method which ensure a rapid completion of the processing cycle without depletion of reactive gas or vapor over the substrate surface. It is also another object to provide versatility and improved control of the flow by utilizing injectors of various configurations and by operating the apparatus in a continuous, pulsed, or combined modes. It is yet another object is to reduce the consumption of chemical and to speed-up the process due to a reduced volume and shortened path length of chemicals in the delivery system. Still another object is to provide an apparatus that ensures effective and efficient separation of highly reactive gases prior to delivery to the target surface in operational space along with uniform surface coverage and the shortest gas residence time in the delivery system.

The present invention provides an apparatus and method for radical-assisted monolayer processing by employing a reactor with at least two linear injectors arranged in diametrical direction of the substrate and injecting reactive gases and radicals sequentially onto the treated surface of the substrate with a relative motion between the injectors and the substrate. In an alternate embodiment of the invention, the injectors are mounted coaxially either as linear slots or as tubes with perforations. An injector connected to a downstream chemical precursor source that is connected to a pulsed plasma source is mounted above the substrate such that the flow from the injector impinges on the substrate. The chamber is connected to a pump through a gate valve and a throttle valve. A chemical precursor pulse and a plasma pulse are synchronized to achieve activation of the chemical precursor by radicals downstream of a pulsed plasma source. Chemical precursors are either excited in the gas phase or directly on the surface. In the first step, a first chemical precursor, in molecular or radical form, is injected from the first injector; in the second step an inert or carrier gas pulse sweeps the surface to remove excess precursor. Optionally, excited atoms from carrier gas plasma are pulsed on the surface to activate the adsorbed precursor monolayer on the substrate surface. In the third step, second precursor is injected downstream of the second pulsed plasma source to obtain radicals that are injected on the substrate to affect rapid chemical reaction with the chemisorbed monolayer of the first chemical precursor. Finally in the fourth step, only radicals from the second plasma source are injected on the surface to sweep the reaction by-products and further prepare the surface for the next cycle. The gases injected in the active plasma region are such that they do not form a solid residue upon dissociation. The cycle can be repeated to process the film of a desired dimension with monolayer precision. In a preferred embodiment, substrate is mounted on a suitably activated substrate holder within a substantially circular chamber with an annular gap between the substrate holder and the inner surface of the chamber. During each gas injection step the substrate rotates at least half the rotation. Optionally the reactor can be operated in a continuous gas or vapor flow and pulsed plasma mode or continuous flow and constant power (CW) plasma mode, and the rate of processing can be modulated. Operational advantages of such an apparatus and process are high speed, lower process temperature, substantial reduction in ion damage, and precision monolayer processing with uniform and highly conformal surface coverage over the entire substrate surface.

### BRIEF DESCRIPTION OF THE DRAWINGS

FIG. 1A is a schematic vertical cross section view of the apparatus of the invention with two parallel diagonally arranged linear injectors.

FIG. 1B is a cross-sectional view of the linear injectors above the substrate in the direction of line IB-IB of FIG. 1A.

FIG. 2 is a three-dimensional view of linear injectors according to one embodiment of the invention for use in conjunction with the apparatus of FIG. 1A; a part of the injectors is removed to show arrangement of vanes.

FIGS. 3A-3C are examples of flow distribution patterns achievable with the use of the injectors of the invention.

FIG. 4 is a three-dimensional view similar to FIG. 2 illustrating two parallel linear injectors with arrangement of inlets different from FIG. 2.

FIGS. 5A-5C are three-dimensional views illustrating three configurations of two linear injector arrangements of the invention in the form of two tubes, one inside the other, with aligned outlet ports.

FIGS. 5D-5F are bottom views illustrating three different arrangements of outlet ports in two injectors arranged side-by-side.

FIG. 6 is a three-dimensional view of linear injectors arranged diametrically across the substrate with intersection in the center of the substrate.

FIG. 7A is a diagram illustrating sequence of operation in a single process cycle with continuous plasma.

FIG. 7B is a diagram illustrating sequence of operation in a single process cycle with pulse plasma.

FIG. 7C is a diagram illustrating a mode of operation with a pulsing flow of the first precursor followed by a pulse of purge gas in combination with a constant flow of second precursor and a constant flow of upstream non-condensable radicals.

FIG. 7D is a diagram illustrating a mode of operation with constant flows of the first precursor and the purge gas in combination with a constant flow of second precursor and a constant flow of upstream non-condensable radicals generated by a pulsed plasma.

### DETAILED DESCRIPTION OF THE INVENTION

The present invention relates to a method and system for providing a file service that automatically stores and organizes digital files of different Mime types. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

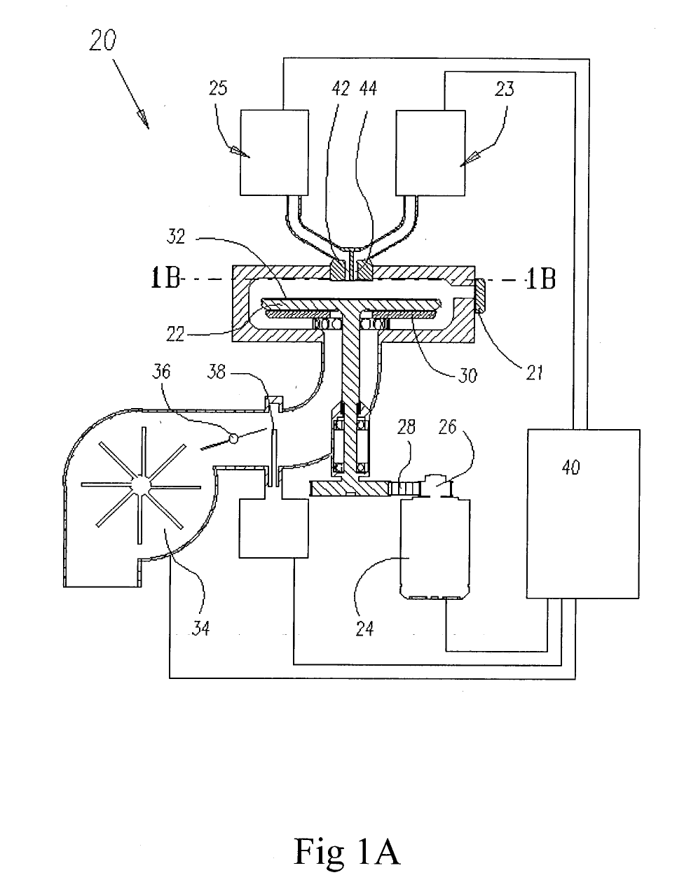

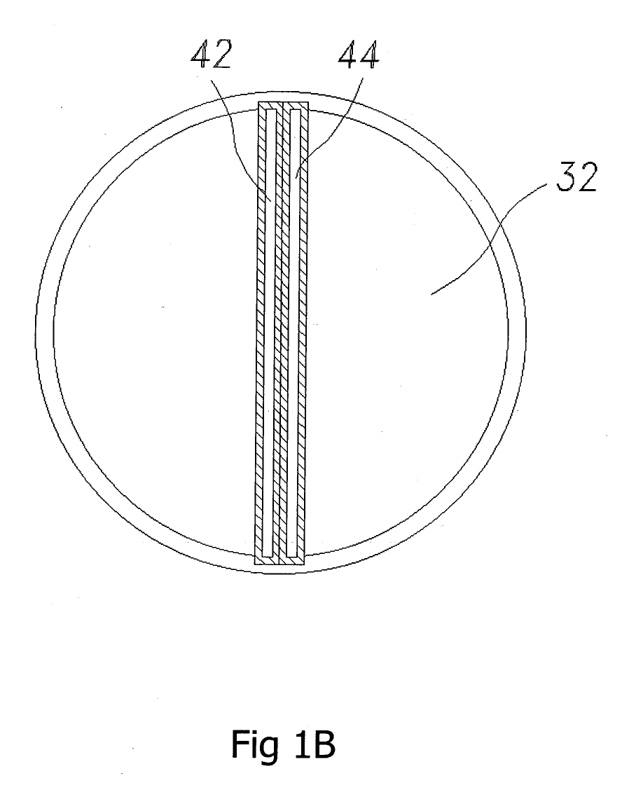

The present invention provides an apparatus and method for radical-assisted monolayer processing in a reactor with linear injectors arranged in diametrical direction of the substrate and injecting reactive gases or radicals sequentially onto the treated substrate surface with a relative motion between the injectors and the substrate FIG. 1A is a schematic vertical cross section view of the apparatus according to a preferred embodiment of the invention with two parallel diagonally-arranged linear injectors, and FIG. 1B is a cross-sectional view of the linear injectors above the substrate in the direction of line IB-IB of FIG. 1A. More specifically, in the preferred embodiment of the apparatus shown in FIGS. 1A and 1B, the apparatus comprises a RAMP reactor, which as a whole is designated by reference numeral 20. The reactor 20 has a substantially circular sealed working chamber 21 which operates at low pressure, e.g., of several hundred mTorr, with a co-axially mounted circular substrate holder 22 that can be rotated, e.g., by a motor 24 via a pulley 26 on the output shaft of the motor 24 via a transmission belt 28 and a driven pulley 27 on the end of a substrate holder shaft 29. A stationary heater 30 is provided underneath the substrate holder 22 to heat a rotating substrate 32 supported by substrate holder 22 to a predefined temperature as stipulated by the process. It is specifically noted here that the arrangement of a substrate heater 30 is desirable as it imparts mobility to the gas molecules on the surface of the substrate 32. Moreover, moderate heating of the substrate 32 can assist in desorption and purging of reaction by-products and also can help to complete exchange reactions more effectively. Although the chemical reactions can be possibly carried out without substrate heating, the inventors' intention to include a substrate heater 30 is to obtain the product with higher purity and with lower defect density.

The reactor 20 is provided with a substrate loading-unloading port 33 that forms a part of the reactor wall and allows loading/unloading the substrates to and from the reactor 20 (FIG. 1A).

The reactor 20 is also connected to a vacuum pump 34 through a throttle valve 36 and a gate valve 38, both operated, e.g., by a programmable controller 40. The reactor 20 is equipped with linear injectors 42 and 44 (FIGS. 1A and 1B) with apertures or continuous slots, which are described in detail later, mounted within the reactor such that the flow emanating from them impinges directly on the substrate 32 underneath. As shown in FIG. 1B, the linear injectors are arranged substantially diametrically across the round substrate 32.

Each of the linear injectors 42 and 44 is supplied with an appropriate chemistry, e.g., reactive radical species from a radical generator 23 (for injector 42) and chemical precursor supply unit 25 for the supply of reactive chemical precursor species. The unit 23 is described in more detail in our pending U.S. patent application Ser. No. 10/288,345 filed on Nov. 4, 2002. It should be noted that the supply units 23 and 25 both have a provision for the supply of a purge gas from sources (not shown).

The unit 25 can be a mere chemistry supply box or an appropriate radical generator of the type described in the aforementioned U.S. patent application. The following description will relate to various embodiments of linear injectors of the invention, which, however, should not be construed as limiting the scope of the application of the invention.

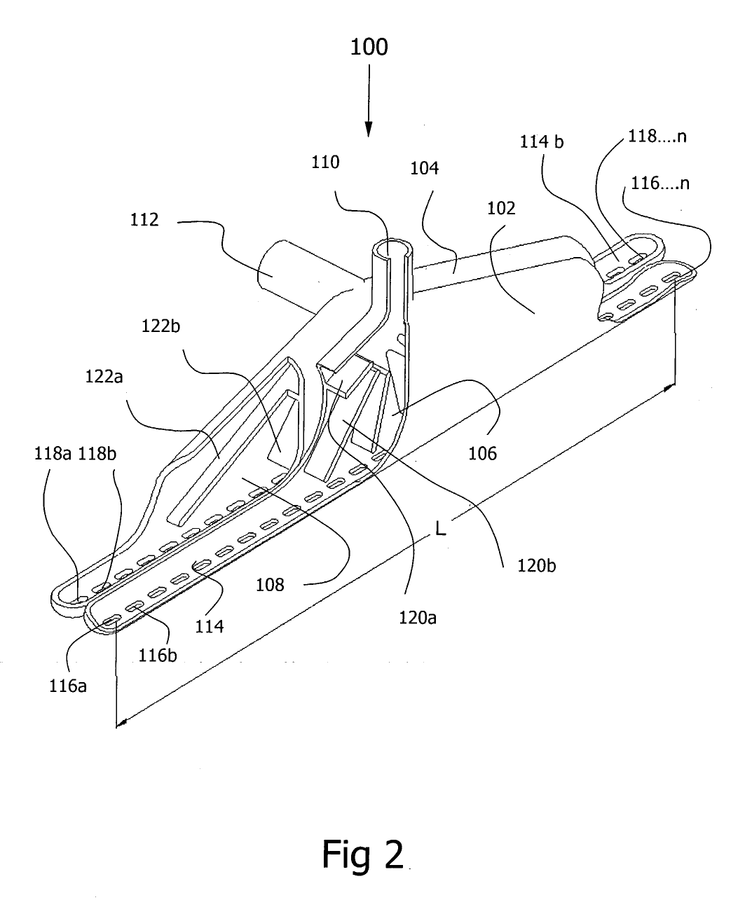

FIG. 2 is a three-dimensional view of linear injector assembly 100 according to one embodiment of the invention for use in conjunction with the apparatus 20 of FIGS. 1A and 1B. It can be seen that the linear injector assembly 100 consists of two parallel linear injectors 102 and 104 arranged side by side. The injectors are made in the form of hollow-tapered nozzles. In order to shown the interior arrangement of shaped cavities 106 and 108 formed inside the injectors 102 and 104, respectively, a part of each injector in FIG. 2 is removed. Reference numeral 110 designates an inlet port of the injector 102, while reference numeral 112 designates an inlet port of the injector 104. Each injector 102 and 104 shown in FIG. 2 has a closed bottom 114a and 114b, respectively, with a plurality of outlet ports 116a, 116b, . . . 116n and 118a, 118b, . . . 118n, respectively. In order to provide a desired distribution of the flow of chemistry supplied to the surface of the substrate 30 (FIG. 1A and FIG. 1B), the cavities 106 and 108 contain a plurality of flow directing vanes 120a, 120b, . . . and 122a, 122b, . . . , respectively. For the same purpose of obtaining a desired distribution of flows on the surface of the substrate 30, the outlet ports 116a, 116b, . . . , 116n and 118a, 118b, . . . , 118n (FIG. 2) may have a variable pitch, different shapes, and cross sections. Although the direction of the inlet port 112 of the injector 104 is shown perpendicular to the direction of the inlet port 110 of the injector 102, both inlet ports can be arranged parallel to each or at an angle, depending on specific design requirements.

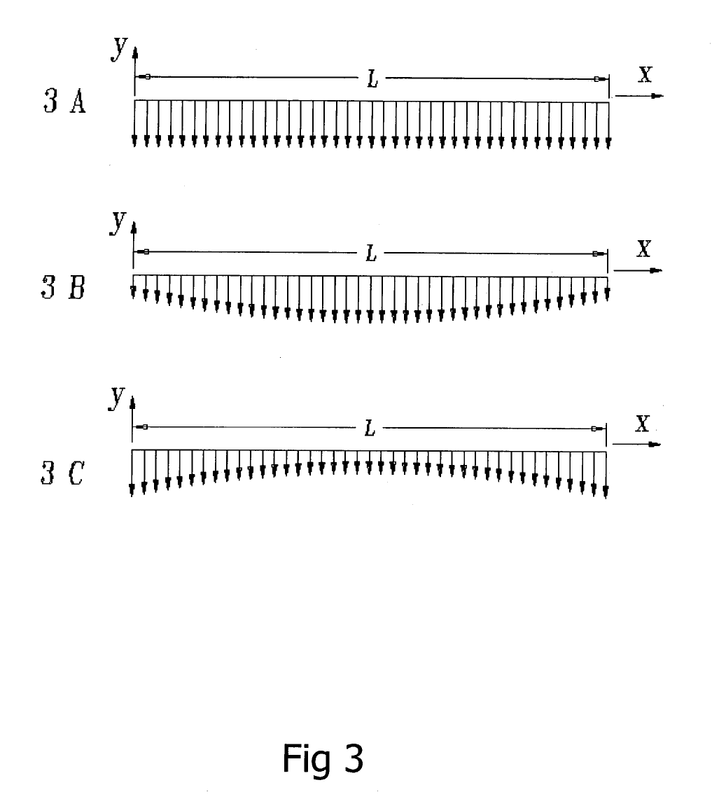

The length L of the injectors (FIG. 2) should be substantially equal to the diameter of the circular substrate 32 (FIGS. 1A and 1B), while the positions of individual vanes 120a, 120b, . . . and 122a, 122b, . . . and their shapes are selected so as to obtain any specific flow pattern, e.g., of the types shown in FIGS. 3A-3C. Though the vanes 120a, 120b, . . . and 122a, 122b, . . . are shown as straight strips, it is understood that they may have a profiled curved surface. Also the distribution patterns are not limited to the three shapes shown in FIGS. 3A, 3B, and 3C. The patterns shown in these drawings may relate to flow velocities, mass, volumes, etc., plotted on the ordinate axis. FIG. 3A relates to the case of uniform distribution of the flow over the entire length L of the linear injector which corresponds to the abscissa axis. FIG. 3B corresponds to the case with higher distribution in the central part of the linear injector. FIG. 3C illustrates the distribution pattern with the lower flow in the center of the linear injector. Many other patterns can be achieved by specifically arranging the vanes.

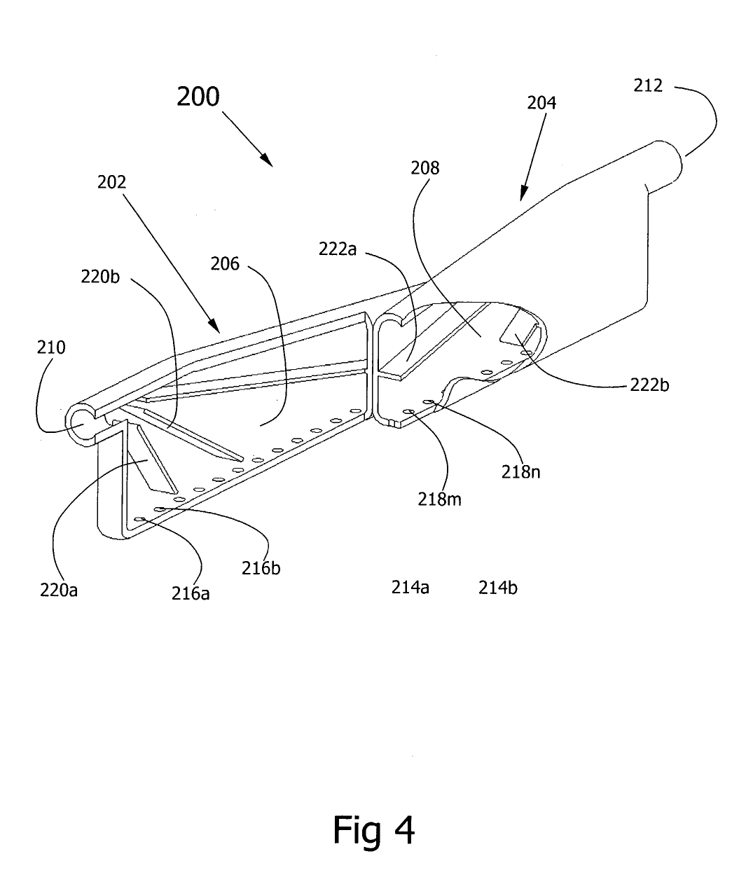

FIG. 4 is a three-dimensional view of linear injector assembly 200 according to another embodiment of the invention for use in conjunction with the apparatus 20 of FIGS. 1A and 1B. It can be seen that the linear injector assembly 200 consists of two parallel linear injectors 202 and 204 arranged side by side. The injectors are made in the form of hollow-tapered nozzles. In order to show the interior arrangement of shaped cavities 206 and 208 formed inside the injectors 202 and 204, respectively, a part of each injector in FIG. 4 is removed. Reference numeral 210 designates an inlet port of the injector 202, while reference numeral 212 designates an inlet port of the injector 204. Each injector 202 and 204 shown in FIG. 4 has a closed bottom 214a and 214b with a plurality of outlet ports 216a, 216b, . . . 216n and 218m, 218n, respectively. In order to provide a desired distribution of the flow of chemistry supplied to the surface of the substrate 32 (FIG. 1A and FIG. 1B), the cavities 2106 and 208 contain a plurality of flow directing vanes 220a, 220b, . . . and 222a, 222b, . . . , respectively. For the same purpose of obtaining a desired distribution of flows on the surface of the substrate 32, the outlet ports 216a, 216b, . . . and 218m, 218n, . . . (FIG. 4) may have a variable pitch, different shapes, and cross sections. Although the direction of the inlet port 212 of the injector 204 is shown perpendicular to the direction of the inlet port 210 of the injector 202, both inlet ports can be arranged parallel to each or at an angle, depending on specific design requirements.

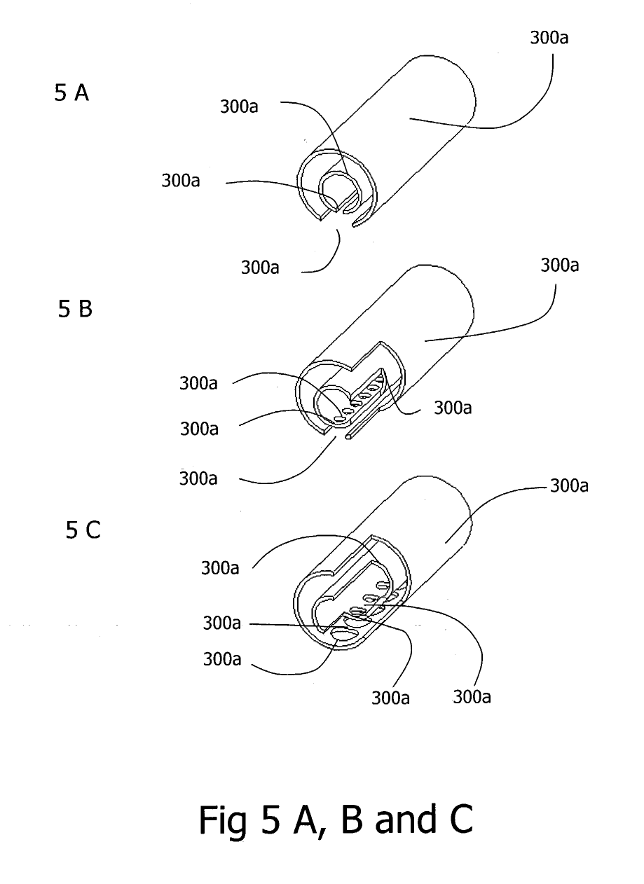

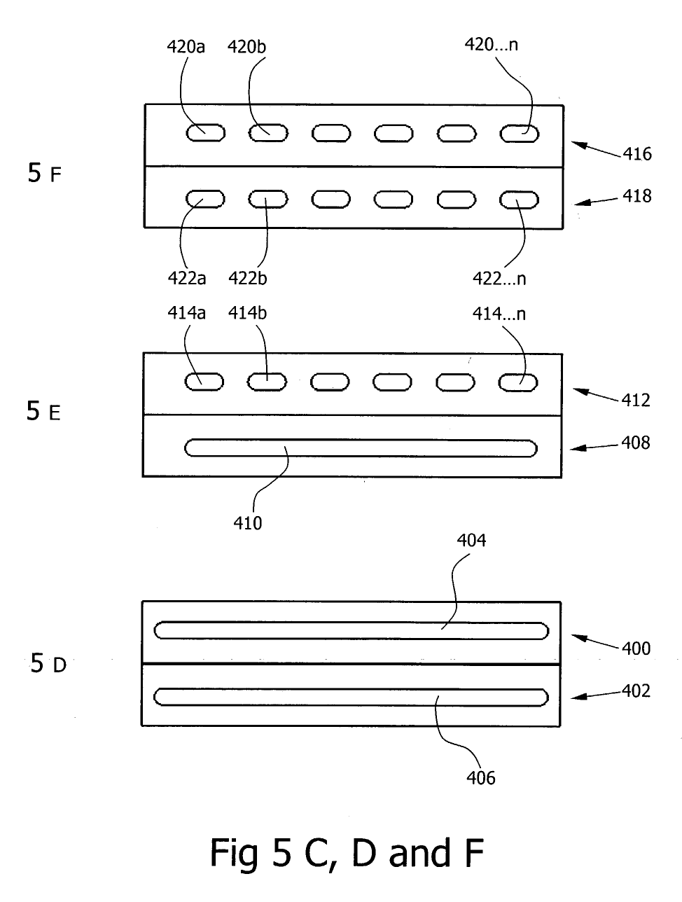

FIGS. 5A-5D are three-dimensional views illustrating four configurations of two linear injector arrangements of the invention in the form of two tubes, one inside the other, with aligned outlet ports.

The arrangement of FIG. 5A comprises two hollow members 300 and 302, one inside the other with their respective outlet ports 300a and 302a being aligned. In the embodiment of FIG. 5A the outlet ports 300a and 302a are shown as longitudinal slot-like openings formed in the sidewalls of the hollow members 300 and 302. Furthermore, although the hollow members are shown tubular with a circular cross section, they may have any other configuration, e.g., with a square or rectangular cross section. Moreover, the inner and outer hollow members may not necessarily be concentric with respect to each other.

The arrangement of FIG. 5B comprises two hollow members 304 and 306, one inside the other with their respective outlet ports being aligned. The outlet ports of the inner member 306 are made in the form of a plurality of outlet openings 306a, 306b, . . . , while the outlet port of the outer member 304 is made in the form of a longitudinal slot-like opening 304a formed in the sidewall of the hollow members 304. Furthermore, although the hollow members are shown tubular with a circular cross section, they may have any other configuration, e.g., with a square or rectangular cross section. Moreover, the inner and outer hollow members may not necessarily be concentric with respect to each other.

The arrangement of FIG. 5C comprises two hollow members 308 and 310, one inside the other with their respective outlet ports being aligned. The outlet ports of both the inner member 310 and the outer member 308 are made in the form of a plurality of outlet openings 310a, 310b, . . . 308a, 308b, . . . , respectively. The outlet ports of both members are shown aligned and of different diameters. Furthermore, although the hollow members are shown tubular with a circular cross section, they may have any other configuration, e.g., with a square or rectangular cross section. Moreover, the inner and outer hollow members may not necessarily be concentric or aligned with respect to each other. The outlet ports may have different shapes in both hollow members as well as within the members.

FIGS. 5D-5F are bottom views illustrating three different arrangements of outlet ports in two injectors arranged side-by-side. The injectors may have the shape of hollow bodies with cavities as shown in FIGS. 1A, 1B, 2, and 4. FIG. 5D corresponds to the embodiment, in which the outlet ports of both injectors 400 and 402 are made in the form of two substantially parallel elongated slots 404 and 406, respectively. FIG. 5E corresponds to the embodiment, in which the outlet port of one of the injectors 408 is made in the form of an elongated slot 410, while the outlet port of the second injector 412 is made in the form of a plurality of elongated openings 414a, 414b, . . . 414n. The outlet ports of both members are shown aligned and of different diameters. Although the outlet ports 414a, 414b, . . . 414n are shown as elongated openings, they may be circular openings or openings of any other shape, size, and distribution. FIG. 5F corresponds to the embodiment, in which the outlet ports of both injectors 416 and 418 are made in the form of plurality of openings 420a, 420b, . . . and 420n, 422a, 422b, . . . 422n, respectively. Although the outlet ports 420a, 420b, . . . and 420n, 422a, 422b, . . . 422n are shown as elongated openings, they may be circular openings or openings of any other shape, size, and distribution.

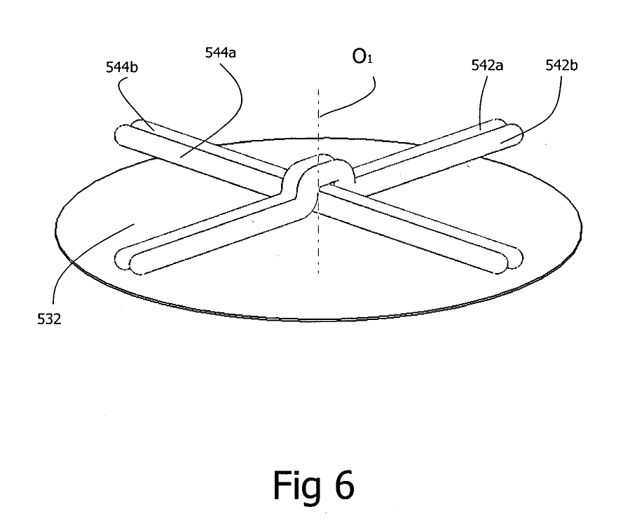

FIG. 6 is a three-dimensional view of linear injector assemblies arranged diametrically across the substrate with intersection in the center of the substrate. As shown in this drawing, two linear injector assemblies, each composed of a pair of injectors 542a, 542b and 544a, 544b, respectively, are arranged perpendicular to each other, i.e., at 90° to one another and intersect in center O₁ of the substrate 532. Herein, the word “intersecting” is used conventionally, since, as shown in FIG. 6, the mutually perpendicular linear injectors 542a, 542b and 544a, 544b cannot physically intersect with each other but rather overlap each other in the central area of the substrate 532. However, the major working portions of the intersecting linear injectors 542a, 542b and 544a, 544b with their outlet ports (not shown in FIG. 6) lay in the same plane and face the substrate 532. With the embodiment of FIG. 6, the angle of rotation of the substrate sufficient for full coverage of the substrate surface with the chemicals supplied through the injectors will be 90°. This will allow shortening the cycle time.

It is understood that two pairs of diametrically intersecting linear injectors are shown only as an example and that the number of pairs may be different. In general the angle α (FIG. 6) of rotation of the substrate sufficient for full coverage of the substrate surface with the chemicals supplied through the injectors can be expressed as follows:

α=360°/2n,

Where, n is the number of intersecting linear injector assemblies.

Operation of the Apparatus of the Invention

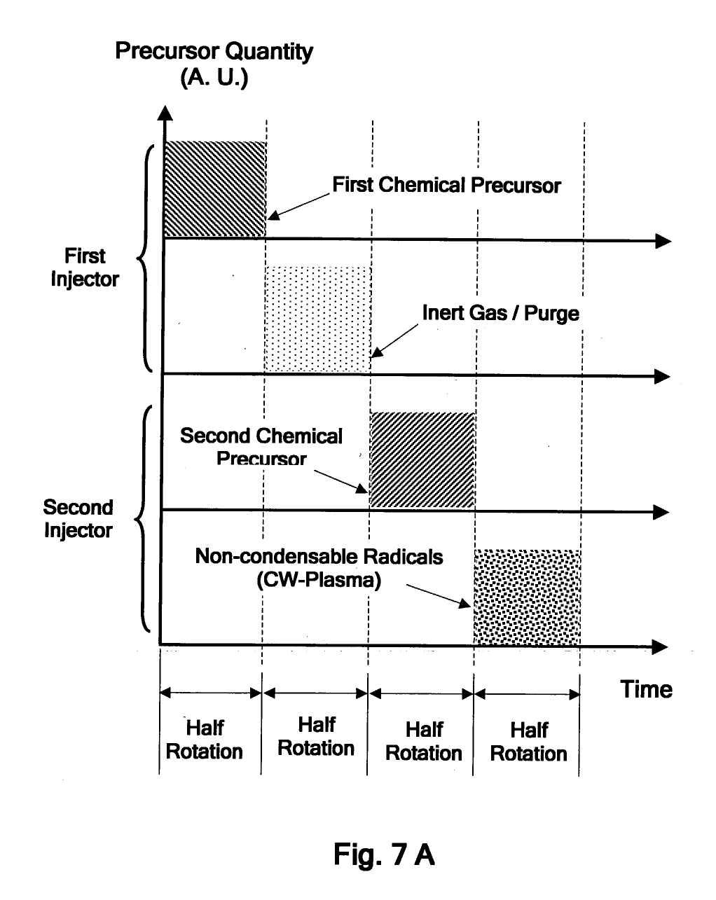

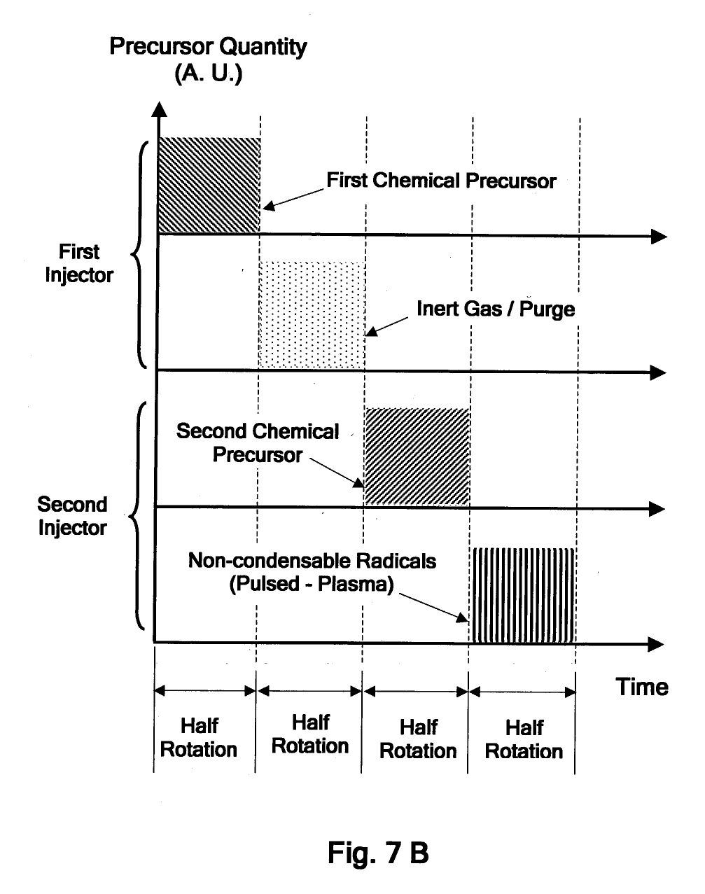

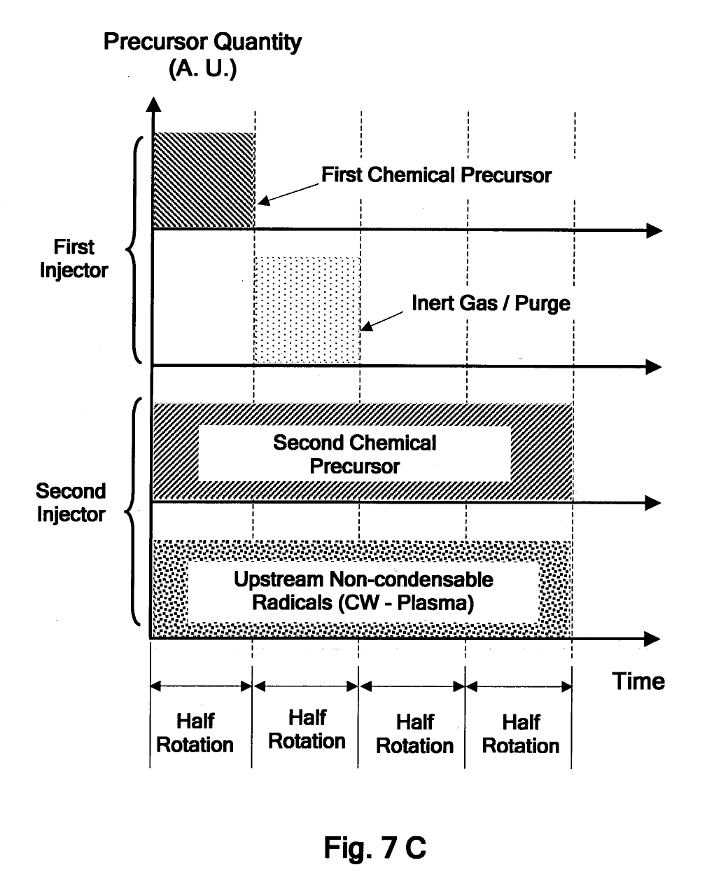

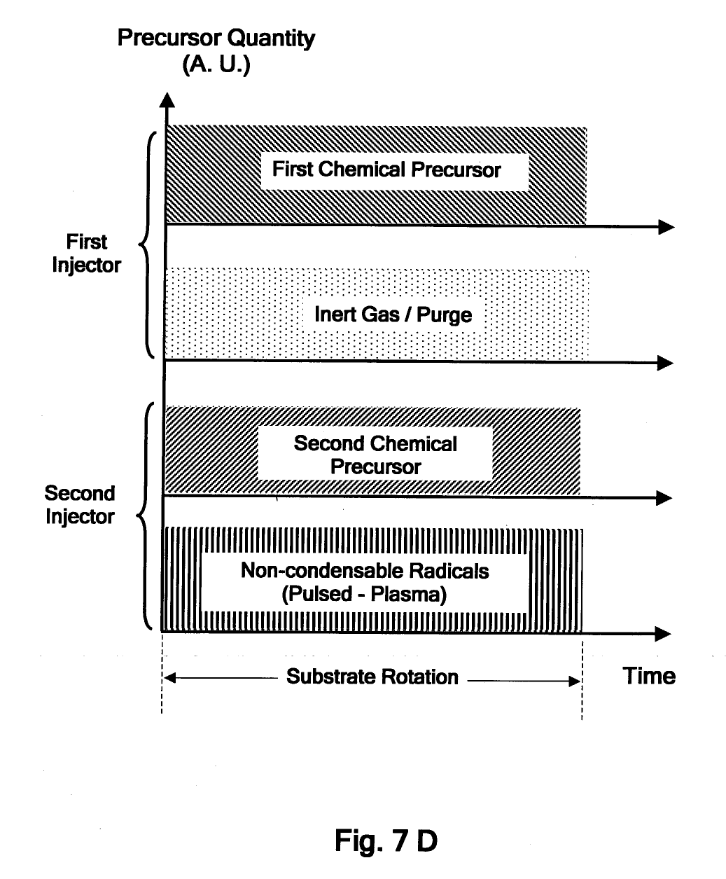

The operation of the invention will now be described with reference to FIGS. 7A, 7B, 7C and 7D, wherein FIG. 7A is a diagram illustrating sequence of operation in a single process cycle with continuous supply of radicals and FIG. 7B is a diagram illustrating sequence of operation in a single process cycle with pulse supply of radicals.

The RAMP reactor 20 (FIGS. 1A and 1B) operates on the principle similar to the one described earlier in U.S. patent application Ser. No. 10/019,244 filed on May 20, 2002. In this particular invention, a linear injector assembly composed of injectors 42 and 44 arranged side by side. It is understood that the injectors 42 and 44 may represent any linear injector assembly described above with reference to FIGS. 2, 4, and 5.

In order to start the processing of the substrate 32 by treating its surface with gaseous reagents supplied from the radical generator 23 and the chemical precursor supply unit 25, a substrate loading-unloading port 33 is opened and the substrate 32 is placed onto the substrate holder 22. The substrate 32 is heated by the heater 30 through the body of the substrate holder 22. The working chamber 21 of the apparatus 20 is evacuated by opening the gate valve 38 and connecting the cavity of the working chamber 21 with a vacuum pump 34 via an adjustable throttle valve 36. All these operations are carried out from the controller 40 (FIG. 1A). The substrate holder 22 with the substrate 32 on it is set into constant rotation from the motor 24 via the pulleys 26 and 27 through the transmission belt 28.

A chemical precursor is then supplied from the chemical precursor supply unit 25 during the time corresponding to half-rotation of the substrate 32 (FIG. 7A). The precursor covers the entire upper surface of the substrate 32 because the injector 44 has a substantially diametrical arrangement relative to the circular substrate 32. During the next half-rotation of the substrate 32, the entire surface of the substrate is purged with a purge gas supplied to the surface of the substrate 32 from the same injector 44. Depending on the process chemistry, the chemical precursor may be exemplified by Silane (SiH₄), Arsine (AsH₃), Gallium Chloride (GaCl₃), Ammonia (NH₃), Tungsten Hexa-fluoride (WF₆) and the purge gas may comprise an inert gas such as Ar, He, N₂, etc., or an active gas such as hydrogen, oxygen, or the like. The first half-rotation supply period of the chemical precursor results into chemisorption of the chemical precursor on the surface of the substrate 32, and the second half-rotation supply period will sweep off the excess chemical precursor from the substrate surface. As a result, a chemisorbed monolayer of the chemical precursor will be formed and remain attached to the surface of the substrate 32.

In the third half-rotation, a first radical-containing gas, such as hydrogen, oxygen, nitrogen, etc., is supplied along with a second gas, which may be a condensable or non-condensable gas, such as silane, phosphine, etc., onto the previously formed chemisorbed monolayer of the chemical precursor from the radical generator 23 via the injector 42. As a result, radicals react with monolayer and form a desired monolayer coating of the types described below in the attached examples. The excess radicals also help purge the reaction by-products and are removed away from the substrate surface by evacuation.

In the last, i.e., the fourth half-rotation of the substrate 32, the supply of the condensable or non-condensable gas is discontinued and the surface is purged with the flow only of the first radical-containing gas. As a result, the substrate surface acquires a final coating of the species from the first radical-containing gas which is receptive towards the chemical precursor supplied during the first half-rotation. The excess radicals are recombined and removed from the system by evacuation.

Subsequently, the next four half-rotation cycle of chemical supply, i.e., tworevolution cycle is initiated and repeated as described above for a desired number of times until a coating of a required thickness is formed.

What was described above was a process, in which the radical-containing gases were supplied in the third and fourth half-rotation periods of the working cycle in a continuous mode. FIG. 7B illustrates a process, in which the radical-containing gases were supplied in the third and fourth half-rotation periods of the working cycle in a pulse mode.

FIG. 7C illustrates a process, in which a first chemical precursor is supplied through the first injector only for the time duration during which the substrate rotates at least half rotation. During the next half rotation, an inert or purge gas pulse in injected on the substrate and the chamber is purged. During both these pulses, the second injector maintains a constant flow of second precursor combined with the upstream flow of non-condensable radicals. The substrate is maintained in constant angular motion during the processing.

FIG. 7D illustrates a process, in which a first chemical precursor along with an inert gas or purge gas is supplied through the first injector and the a constant flow of second precursor second gas along with upstream non-condensable radicals generated by a pulsed plasma are simultaneously supplied to the substrate which is maintained in a constant angular motion.

It is understood that diagrams of the type shown in FIGS. 7A-7D for the processes with the use of parallel and/or coaxial linear injectors, which require rotation of the substrate at least through 1800, will be different for the case of FIG. 6 with intersecting linear injector assemblies, but the principle of creation of the diagrams will be the same with indication of rotation through angle α=360°/2n.

Modes of the reactor operation with other combinations of the precursor and radical-containing gases are possible. For example, the chemical precursor may be supplied in an intermittent mode such that it covers the substrate surface entirely while the radical-containing gases may be supplied continuously to the substrate rotating at a constant speed. In another embodiment, both the chemical precursor and the radical-containing gases may be supplied in a continuous mode to the substrate rotating at a constant speed.

The method of the invention based on the used of the apparatus of the invention will now be described with reference to the practical examples given below which are given only for illustrative purposes and should not be construed as limiting the scope of the application of the invention.

### EXAMPLE—1

Deposition of metals at lower temperature: A variety of metals deposition processes can be developed by employing the RAMP (Radical Assisted Monolayer Process) cycle with metal halide as a metal precursor, He/Ar/N₂ as gas 1 through the first injector and hydrogen radicals through the second injector. Binary metallic hydrides in which metals react with hydrogen are known in the prior art (cf. F. A. Cotton and G. Wilkinson, in Advanced Inorganic Chemistry, ch. 5, 3^{rd} ed., John Wiley, New York, 1972) and metal halides can be conveniently and suitably generated in-situ by heating the respective metals in presence of hydrogen chloride (HCl) or hydrogen bromide (HBr) gas. Halides such as titanium tetrachloride and tungsten hexafluoride are volatile liquid and gas respectively at room temperature and can be transported in to the RAMP reactor through an injector with relative ease. The process sequence can be broadly described as follows: For the sake of simplicity, the chemical reactions described in throughout the text are not balanced and the surface is assumed to be terminated by an —OH (hydroxyl) species:

(a) 1^{st} pulse through first Injector—half rotation

M-Xₙ+Surface-(OH)→O-M-X₍ₙ₋₁₎+HX (surface adsorption on a hydroxylated surface)

(b) 2^{nd} pulse through first injector—one full rotation

M-X₍ₙ₋₁₎+He/Ar/N₂→M-X_{(n-1) [monolayer]} (adsorbed monolayer formation)

(c) 3^{rd} pulse through second injector—one and half rotation

M-X₍ₙ₋₁₎+.H→M+(n−1)HX (halide reduction to metal)

(d) 4^{th} pulse through second injector—two full rotations

M+.H→M-H (metal hydride bond formation)

(e) 1^{st} pulse of the next cycle through first injector—

M-H+M-Xₙ→M-M-X₍ₙ₋₁₎+HX (next cycle 1^{st} pulse)

In the reaction sequence described above, steps (c) and (d) may be combined together. Here, M=Al, Ti, Ta, Zr, Nb, Hf, Mo, W, Co, Ni, Cu and X=F, Cl, Br and I. Heating the substrate in the temperature range of 50-300 degree C. is desirable to respective RAMP processes. Also, organometallic compounds such as trimethyl aluminum [Al(CH₃)₃] for aluminum and Cu(II) hexa-fluoro-acetyl-acetonate, Cu(hfac)₂ or Cu (II)-2,2,6,6-tetramethyl-3-5-heptanedionate Cu(thd)₂ to deposit copper can be effectively used in place of respective chlorides. Processes for atomic layer deposition (ALD) of copper are known, for example: Martensson et al., described ALD of copper in the paper published in the J. Electrochem. Soc., vol. 145, p. 2926-2931, August 1998, employing Cu (II)-2,2,6,6-tetramethyl-3-5-heptanedionate, [Cu (thd)₂] with molecular hydrogen in the temperature range of 190-260 degree C. In yet another publication, Martensson et al., described ALD of copper in Chemical Vapor Deposition, vol. 3, p. 45-50, 1997, by employing CuC₁ and H₂ in a temperature range of 300-400 degree C. Employing .H in place of H₂ should significantly advance the ALD process at lower temperature. Moreover, gettering of undesired elements such as Cl, C with .H should be more efficient as compared to H₂.

### EXAMPLE—2

Deposition of Metal Oxides: A variety of oxides of corresponding metals can be deposited by employing metal halides through the first injector and upstream hydrogen plasma with oxygen injected downstream through the second injector. Reaction of .H with O₂ downstream leads to the formation of .OH radicals that react with metal halide monolayer. In the last step, O₂ flow is switched off and the flow of .H radicals to the surface results in to the formation of M-OH species.

(a) 1^{st} pulse—first injector—half rotation

M-Xₙ+Surface-(OH)→O-M-X₍ₙ₋₁₎+HX (surface adsorption on a hydroxylated surface)

(b) 2^{nd} pulse—first injector—one full rotation

M-X₍ₙ₋₁₎+He/Ar/N₂→M-X₍ₙ₋₁₎ [monolayer] (adsorbed monolayer)

(c) 3^{rd} pulse—second injector downstream O₂ and upstream .H—one and half rotation

M-X₍ₙ₋₁₎+[.H+O₂]→M-O+(n−1)HX (metal halide reaction with OH)

(d) 4^{th} pulse—switch off downstream O₂ and continue upstream .H—second injector two full rotations

M-O+.H→M-OH (metal hydroxide formation)

(e) 1^{st} pulse of the next cycle (first injector):

M-OH+M-Xₙ→M-O-M-X₍ₙ₋₁₎+HX (next cycle . . . 1^{st} pulse)

Alternately, O₂ can be injected in to the plasma cavity and H₂ injected downstream and in the last step, only H₂ flow is maintained to form surface OH group attached to metal. Examples of M are, but not limited to: Al, Ti, Ta, Zr, Nb, Hf, Mo, W, Co, Ni, and Cu. Whereas, X=F, Cl, Br or 1.

### EXAMPLE—3

Deposition of Metal Nitrides: A variety of oxides of corresponding metals can be deposited by employing metal halides through the first injector and upstream hydrogen plasma with nitrogen injected downstream through the second injector. N₂ or ammonia (NH₃) is injected upstream of the second injector in the plasma cavity and H₂ is injected downstream and in the fourth half rotation, only H₂ flow is maintained. Alternately, .NHₓ species are generated by hydrogen plasma upstream with N₂ injection downstream. The NHₓ species react with metal halide monolayer. In the last step, N₂ flow is switched off and the flow of .H radicals to the surface results in to the formation of M-NH₂ species.

(a) 1^{st} pulse—first injector—half rotation

M-Xn+Surface-(OH)→O-M-X (n−1)+HX (surface adsorption on a hydroxylated surface)

(b) 2nd pulse—first injector—one full rotation

M-X₍ₙ₋₁₎+He/Ar/N₂→M-X₍ₙ₋₁₎ [monolayer] (adsorbed metal-halide monolayer)

(c) 3^{rd} pulse—second injector—downstream H₂ and upstream N₂: one and half rotation

M-X₍ₙ₋₁₎+[.H+N₂]→M-NH.+(n−1)HX (metal halide reaction with .NH)

(d) 4^{th} pulse—second injector—switch off downstream N₂ and continue upstream .H—two full rotations

M-NH.+.H →M-NH₂ (metal-NH₂ bond formation)

(e) 1^{st} pulse of the next cycle (first injector)—

M-NH₂+M-Xₙ→M-N-M-X₍ₙ₋₁₎+HX (next cycle . . . 1^{st} pulse)

Alternately, N₂+H₂ mixture is injected in to the plasma cavity in the third step and in the fourth step only H₂ flow is maintained to generate —NH₂ group attached to the metal atom. In yet another mode, NH₃ is used as a third gas and injected downstream while H₂ is used as the second gas in the plasma cavity to facilitate NH₂ group formation. Examples of M are, but not limited to, Al, Ti, Ta, Zr, Nb, Hf, Mo, W, Co, Ni, Cu. X is selected from F, Cl, Br or I. Alternately, organometallic compounds such as trimethyl aluminum can be suitably used as an Al source.

### EXAMPLE—4

Deposition of Metal Carbides: Metal carbides are deposited by employing hydrogen as a second gas and methyl halide (CH₃X) in the downstream flow as a third gas in combination with metal halides. Other sources of carbon such as alkanes with general formula CnH₂ₙ₊₂, for example, CH₄, C₂H₆ or benzene C₆H₆ are equally useful. Some examples of metal halides are: SiCl₄, TiCl₄, WF₆, MoF₆, TaCl₅, ZrCl₅ and so on. The mechanism of deposition of carbides can be described as below:

(a) 1^{st} pulse—first injector—first half rotation

M-Xₙ+Surface-(OH)→O-M-X₍ₙ₋₁₎+HX (surface adsorption on a hydroxylated surface)

(b) 2^{nd} pulse—first injector—one full rotation

M-X₍ₙ₋₁₎+He/Ar/N₂→M-X₍ₙ₋₁₎[monolayer] (adsorbed monolayer)

(c) 3^{rd} pulse—downstream CH₃X and upstream .H—second injector—one and half rotation

M-X₍ₙ₋₁₎+[.H+CH₃X]→M-C—H.+(n)HX (metal halide reaction with .CH₃)

(d) 4^{th} pulse—switch off downstream CH₃Cl/CH₃F and continue upstream .H second injector—two full rotations

M-C—H.+.H→M-CH₃ (metal carbon bond formation)

(e) 1^{st} pulse of the next cycle (first injector)—

M-CH₃+M-Xₙ→M-C-M-X₍ₙ₋₁₎+HX (next cycle . . . 1st pulse)

### EXAMPLE—5

Deposition of Metal Carbonitrides: Metal carbonitrides with general formula MCxNy are deposited by employing metal halide as a metal source such as TiCl₄, WF₆, SiCl₄ etc., injected as the first gas and hydrogen as the second gas with mixture of gases containing C and N injected downstream. The appropriate sources of C are alkanes (general formula—CₙH₂ₙ₊₂, e.g. CH₄—methane) or alkyl halide (general formula R—X, such that R=CH₃, C₂H₅ and X=F, Cl, Br) and appropriate source of N can be ammonia. Composition of carbon containing vapor or gas and ammonia is varied independently. Alternately, alkyl amine (general formula R—NH₂) can be injected downstream along with hydrogen as an upstream gas in the plasma cavity in the second injector.

### EXAMPLE—6

Deposition of Metal Borides: Borides are deposited by employing appropriate metal source such as TiCl₄, WF₆ etc. and hydrogen as the second gas along with diborane (B₂H₆) as a boron source injected downstream.

### EXAMPLE—7

Deposition of Phosphides, Arsenides and antimonides: Metal halides or organometallics such as alkyls of gallium, indium, aluminum as metal sources are combined hydrogen as a second gas with phosphine (PH₃), arsine (AsH₃) or Sb (CH₃)₃ as a third gas/vapor is used to deposit thin films of various desired compounds. Highly reactive hydrogen radicals are effectively used to extract Cl and C as contaminants in the films due to their excellent scavenging capacity.

### EXAMPLE—8

Deposition of Metal Silicides: metal silicides are deposited by injecting metal halides or corresponding organometallic-compounds through the first injector. Hydrogen is employed in the plasma cavity upstream the second injector with silane (SiH₄) or mono-chloro-silane (SiH₃Cl) being injected downstream to effectively generate SiH₃ radicals. In the last step, only flow of .H is maintained.

### EXAMPLE—9

Deposition of Metal Chalcogenides (Sulfides, Selenides and Tellurides): metal sulfides are effectively deposited by employing metal halides or organometallics in combination with hydrogen radicals generated upstream in the second injector with hydrogen sulfide (H₂S) or hydrogen selenide (H₂Se) being injected downstream generate .HS and .HSe radicals respectively that react with the chemisorbed halide monolayer.

### EXAMPLE—10

Deposition of ternary and quaternary compounds and alloys: ternary and quaternary compounds are deposited by pulsing a mixture of metal halides or organometallic compounds of metals in the first step in the predefined composition. For example, in the synthesis of AlₓGa₍₁₋ₓ₎ As thin films, precursors of Al and Ga (such as trialky Al and trialkyl Ga or AICl₃ and GaCl₃) are mixed together in a predefined proportion and the mixture is injected in the reactor in the first step through the first injector. Arsine is employed in a downstream mode with hydrogen as a non-condensable gas in the active plasma in the third and fourth step through the second injector.

Similarly, ternary compounds such SiCxNy are deposited by employing SiCl₄ or SiH₂Cl₂ as a silicon source. Hydrogen is employed in the plasma cavity upstream to generate .H and a mixture of CH₃C₁ and NH₃ in a predetermined composition is injected downstream the plasma cavity. The resultant mixture is injected through the second injector.

Alloys are deposited by mixing halides or organometallic compounds of metals in the predetermined composition in the first step with hydrogen as the second and third gas together.

### EXAMPLE—11

Multi-layer laminates: multi-layer laminates such as titanium oxide/silicon oxide/titanium oxide/silicon oxide/. . . are deposited by alternately injecting titanium halide and silicon halide through with H₂ as a second (non-condensable) gas through the plasma and O₂ as the third gas in a downstream mode. The thickness of each layer can be independently modulated.

### EXAMPLE—12

Si, Ge, SiₓGe₍₁₋ₓ₎ deposition: SiCl₄ or SiH₂Cl₂ with .H is used for silicon. GeCl₄ and .H is used for deposition of Germanium. A mixture of SiH₄ or SiH₂Cl₂ and GeCl₄ in predefined proportion with .H is used to deposit SiₓGe₍₁₋ₓ₎ alloy. Alkyls of silicon and germanium can be employed in place of halides. Alternately, silane and germane can be employed together.

Thus it has been shown that the present invention provides an apparatus and method for efficient delivery of process fluids, such as radical-containing gases and chemical precursors, to a surface to be processed. The aforementioned apparatus and method ensure a rapid completion of the processing cycle without depletion of reactive gas or vapor over the substrate surface. The invention provides versatility and improved control of the flow by utilizing injectors of various configurations and by operating the apparatus in a continuous, pulsed, or combined modes. The method and apparatus of the invention reduce the consumption of chemical and speed-up the process due to a reduced volume and shortened path length of chemicals in the delivery system. The apparatus ensures effective and efficient separation of highly reactive gases prior to delivery to the target surface in operational space along with uniform surface coverage and the shortest gas residence time in the delivery system.

The invention has been shown and described with reference to specific embodiments, which should be construed only as examples and do not limit the scope of practical applications of the invention. Therefore any changes and modifications in technological processes, constructions, materials, shapes, and their components are possible, provided these changes and modifications do not depart from the scope of the patent claims. For example, a large variety of chemical processes can be developed by employing the apparatus and methods described above. Also, the process sequence can be suitably modified according to process chemistry and the desired product; however, all such modifications will fall within the scope of the invention. The operation of such a reactor can be modulated over a wide range of process parameters such as pulse widths; pulsing frequency and power of the plasma, plasma pulsing frequency and plasma power duty cycle and flow rates of gases. In addition to deposition, the invention is equally applicable to other broad areas of processing such as etching or removal of material, striping of photoresist, post-etch or post-ash cleaning of residues in the microstructures and removing deposits on the inner surfaces of the processing chamber and so on. It thus encompasses a broad area of substrate processing and inventors term it “Radical-Assisted Monolayer Processing”—“RAMP” and the processing chamber is termed RAMP reactor. Moreover, it is not restricted to a particular chemical process and a wide range of chemistries can be effectively performed within its scope. Such apparatus and methods of substrate processing are taught in sufficient and enabling detail. The substrate is not necessarily round in shape and may have a square, rectangular, polygonal or any other shape. More than one substrate can be treated simultaneously. Various combinations and arrangements of the linear injectors different from those shown and described are possible. In the case of an injector assembly with one injector inside the other, the injectors are not necessarily cylindrical tubes and may have a conical or any other shape.

1. An apparatus for delivery of reactive chemical precursors to the surface to be treated comprising:
a first precursor source which contains a first precursor selected from a group comprising a molecular chemical reagent and free radicals;
a second precursor source which contains a second precursor selected from a group comprising a molecular chemical reagent and free radicals;
a processing chamber which contains an object holder for holding at least one object with said surface to be treated, said object holder having a circular shape with a diameter;
a precursor delivery and application means connected to said a first precursor source and said second precursor source and comprising at least one pair of linear injectors located in said processing chamber and arranged substantially diametrically above said surface to be treated;
means for rotating said object holder;
said pair of linear injectors comprising a first linear injector for the supply of said first precursor and a second linear injector for the supply of said second precursor, said first linear injector and said second linear injector having a mutual arrangement including being substantially parallel to each other and one inside the other.

2. The apparatus of claim 1, wherein said first linear injector and said second linear injector each has at least one outlet port.

3. The apparatus of claim 2, further comprising a first inlet port for delivering said first precursor to said first linear injector and a second inlet port for delivering said second precursor to said second linear injector, said first linear injector and said second linear injector each having two opposite ends, spaced from each other at a distance substantially equal to said diameter, and an intermediate portion between said ends, said inlet port of each of said first linear injector and of said second linear injector being located in a position selected from the group consisting of any of said ends and said intermediate portion.

4. The apparatus of claim 3, further provided with controlling means for controlling operation of said first precursor source, said second precursor source, and said means for rotating said object holder so that said surface to be treated is processed completely during at least half-rotation of said object holder.

5. The apparatus of claim 3, wherein at least one of said first linear injector and said second linear injector being further provided with fluid distribution means for defining a flow of said fluid to any point of said at least one outlet port across said diameter.

6. The apparatus of claim 4, wherein at least one of said first linear injector and said second linear injector being further provided with fluid distribution means for defining a flow of said fluid to any point of said at least one outlet port across said diameter.

7. The apparatus of claim 5, wherein said fluid distribution means comprise a plurality of vanes extending between said inlet port of said at least one linear injector and said at least one outlet port.

8. The apparatus of claim 6, wherein said fluid distribution means comprise a plurality of vanes extending between said inlet port of said at least one linear injector and said at least one outlet port.

9. An apparatus for delivery of reactive chemical precursors to the surface to be treated comprising:
a first precursor source which contains a first precursor selected from a group comprising a molecular chemical reagent and free radicals;
a second precursor source which contains a second precursor selected from a group comprising a molecular chemical reagent and free radicals;
a processing chamber which contains an substrate holder for holding a substrate with said surface to be treated, said substrate holder having a circular shape with a diameter;
a pair of linear injectors located in said processing chamber and arranged substantially diametrically above said surface to be treated, said pair comprising a first linear injector for the supply of said first precursor and a second linear injector for the supply of said second precursor;
means for rotating said substrate holder;
at least one of said first linear injector and said second linear injector being further provided with fluid distribution means for defining a flow of said fluid to any point of said at least one outlet port across said diameter;
said pair of linear injectors comprising a first linear injector and a second linear injector which have a mutual arrangement including being substantially parallel to each other and one inside the other, each of said first linear injector and a second linear injector having at least one inlet port and outlet means selected from a group comprising a slit arranged substantially along said diameter and a plurality of outlet openings arranged substantially along said diameter.

10. The apparatus of claim 9, wherein said first linear injector and said second linear injector each having two opposite ends, spaced from each other at a distance substantially equal to said diameter, and an intermediate portion between said ends, said at least one inlet port of each of said first linear injector and of said second linear injector being located in a position selected from a group comprising any of said ends and said intermediate portion.

11. The apparatus of claim 10, further comprising controlling means for controlling operation of said first precursor source, said second precursor source, and said means for rotating said object holder so that said surface to be treated is processed completely during at least half-rotation of said object holder.

12. The apparatus of claim 8, wherein said object holder has a central area, each said pair of linear injectors comprises a linear injector assembly, said apparatus having at least two said assemblies which are arranged substantially diametrically across said object holder and intersect with each other in said central area at an angle α equal to 360°/2n, where n is the number of said linear injector assemblies.

13. The apparatus of claim 12, wherein said pair of linear injectors comprises a first linear injector and a second linear injector which have a mutual arrangement selected from parallel to each other and one inside the other.

14. The apparatus of claim 13, wherein said first linear injector and said second linear injector each has at least one outlet port.

15. The apparatus of claim 14, further comprising a first inlet port for delivering said first precursor to said first linear injector and a second inlet port for delivering said second precursor to said second linear injector, said first linear injector and said second linear injector each having two opposite ends, spaced from each other at a distance substantially equal to said diameter, and an intermediate portion between said ends, said inlet port of each of said first linear injector and of said second linear injector being located in a position selected from the group consisting of any of said ends and said intermediate portion.

16. The apparatus of claim 15, further provided with controlling means for controlling operation of said first precursor source, said second precursor source, and said means for rotating said object holder so that said surface to be treated is processed completely during at least half-rotation of said object holder.

17. The apparatus of claim 15, wherein at least one of said first linear injector and said second linear injector being further provided with fluid distribution means for defining a flow of said fluid to any point of said at least one outlet port across said diameter.

18. The apparatus of claim 16 wherein at least one of said first linear injector and said second linear injector being further provided with fluid distribution means for defining a flow of said fluid to any point of said at least one outlet port across said diameter.

19. The apparatus of claim 17, wherein said fluid distribution means comprise a plurality of vanes extending between said inlet port of said at least one linear injector and said at least one outlet port.

20. The apparatus of claim 18, wherein said fluid distribution means comprise a plurality of vanes extending between said inlet port of said at least one linear injector and said at least one outlet port.

21. A method for delivery of reactive chemical precursors to the surface of an object to be treated, comprising the steps of:
providing an apparatus comprising: a source of a non-reactive gas for the supply of a non-reactive gas; a first precursor source which contains a first precursor selected from a group comprising a molecular chemical reagent and free radicals; a second precursor source which contains a second precursor selected from a group comprising a molecular chemical reagent and free radicals; a processing chamber which contains an object holder for holding at least one object with said surface to be treated, said object holder having a circular shape with a diameter; a precursor delivery and application means connected to said a first precursor source and said second precursor source and comprising at least one pair of linear injectors located in said processing chamber and arranged substantially diametrically above said surface to be treated; means for rotating said object holder; and controlling means for controlling operation of said first precursor source, said second precursor source, and said means for rotating said object holder so that said surface to be treated is processed completely during at least a part of rotation of said object holder, said pair of linear injectors comprising a first linear injector for the supply of said first precursor and a second linear injector for the supply of said second precursor, said first linear injector and said second linear injector having mutual arrangement including being substantially parallel to each other and one inside the other;
placing said object onto said object holder inside said processing chamber;
placing said object onto said object holder inside said processing chamber;
evacuating said processing chamber;
supplying said first precursor to the surface of said object through said first linear injector during a first part of rotation, which is equal to said at least a part of rotation, for saturating said surface with said first precursor to form the surface saturated with said first precursor;
supplying said non-reactive gas to the surface of said object through said first linear injector during a second part of rotation, which is the same as said at least part of rotation, for removing an excess of said first precursor from said surface saturated with said first precursor thus forming a chemisorbed monolayer of said first precursor;
supplying said second precursor to said chemisorbed monolayer through said second linear injector during a third part of rotation, which is equal to said at least part of rotation; and
supplying said free radicals to said chemisorbed monolayer through a linear injector selected from said first linear injector and said second linear injector during the fourth part of rotation, which is equal to at least said part of rotation.

22. The method of claim 21, wherein said step of supplying said free radicals to said chemisorbed monolayer is carried out by rotating said substrate holder for more than said at least part of rotation.

23. The method of claim 22, wherein said step of steps of supplying said first precursor and said non-reactive gas are carried out by rotating said substrate holder for more than said at least part of rotation and simultaneously with the supply of said free radicals.
